(19) United States
(12) Patent Application Publication
(10) Pub. No.: US 2015/0026529 A1
(43) Pub. Date: Jan. 22, 2015

(54) SEMICONDUCTOR DEVICE AND METHOD OF EVALUATING SEMICONDUCTOR DEVICE

(71) Applicant: LAPIS SEMICONDUCTOR CO., LTD., Kanagawa (JP)

(72) Inventors: Tetsuya TANABE, Kanagawa (JP); Masahiro MIYAZAKI, Kanagawa (JP)

(21) Appl. No.: 14/306,274

(22) Filed: Jun. 17, 2014

(30) Foreign Application Priority Data
Jul. 16, 2013 (JP) 2013-147707

(51) Int. Cl. G11C 29/08

(52) U.S. Cl. CPC G11C 29/08
USPC 714/719

(57) ABSTRACT

A semiconductor device includes a plurality of memory cell array units and a test circuit unit. The test circuit unit includes a test data generating unit configured to generate a test data piece per test cycle including a writing period and a retrieving period; an expected value register configured to output the test data piece as an expected value data piece; a memory cell driving unit configured to supply a writing driving signal during the writing period, and a retrieving driving signal during the retrieving period; a data relay switching unit configured to supply the test data piece during the writing period, and to output retrieved data piece during the retrieving period; and a determining unit configured to determine whether the retrieved data piece output from the data relay switching unit matches the expected value data piece, and to generate a test result signal indicating a determination result.

### BACKGROUND OF THE INVENTION AND RELATED ART STATEMENT

The present invention relates to a semiconductor device and a method of evaluating the semiconductor device. In particular, the present invention relates to a semiconductor device including a memory circuit and a test circuit, and to a method of evaluating the semiconductor device.

As a conventional technique for easily performing an evaluation of a semiconductor integrated product upon shipping out, a self-evaluation test has been known. When the self-evaluation test is performed, in addition to a main circuit, a test circuit is disposed in the semiconductor integrated product. The test circuit is provided for generating test data and inputting the test data into the main circuit. Further, the test circuit is configured to compare an output result upon inputting the test data with an expected value, so that the test circuit determines whether the semiconductor integrated product is passed or failed. When the test circuit is disposed in the semiconductor integrated product, it is not necessary to connect a tester to the semiconductor integrated product as an evaluation object, and to compare the output result with the expected value. Accordingly, it is possible to easily perform the evaluation.

Patent Reference has disclosed a conventional semiconductor integrated product for performing the self-evaluation test relative to a memory circuit disposed in the conventional semiconductor integrated product.
Patent Reference: Japanese Patent Publication No. 10-162600

In the conventional semiconductor integrated product disclosed in Patent Reference, the test circuit is disposed in the conventional semiconductor integrated product. The test circuit includes a test data generating circuit for generating the test data; a control circuit for controlling to write and retrieve the test data into and from the memory circuit; and a comparing unit for comparing data thus retrieved with the expected value.

In the conventional semiconductor integrated product disclosed in Patent Reference, when the self-evaluation test is performed for evaluating the memory circuit, it is necessary to sequentially perform a writing access and a retrieving access to write and retrieve the test data per each address of the memory circuit. Accordingly, it is necessary to take a long time for performing the self-evaluation test of the memory circuit.

In view of the problems of the conventional liquid crystal semiconductor device described above, an object of the present invention is to provide a semiconductor device and a method of evaluating the semiconductor device capable of performing the self-evaluation test in a short period of time.

Further objects and advantages of the invention will be apparent from the following description of the invention.

### SUMMARY OF THE INVENTION

In order to attain the objects described above, according to a first aspect of the present invention, a semiconductor device includes a plurality of memory cell array units and a test circuit unit for performing a self-evaluation test relative to the memory cell array units.

According to the first aspect of the present invention, the test circuit unit includes a test data generating unit for generating a test data piece per test cycle including a writing period and a retrieving period; an expected value register for retrieving and storing the test data piece, and for outputting the test data piece as an expected value data piece; and a memory cell driving unit for supplying a writing driving signal to the memory cell array units to write data during the writing period, and for supplying a retrieving driving signal to the memory cell array units to retrieve the data during the retrieving period.

According to the first aspect of the present invention, the test circuit unit further includes a data relay switching unit for supplying the test data piece to each of the memory cell array units to write data during the writing period of the test cycle, and for retrieving and outputting the retrieved data piece retrieved from each of the memory cell array units during the retrieving period. Further, the test circuit unit includes a determining unit for determining whether each of the retrieved data pieces output from the data relay switching unit matches the expected value data piece, and for generating a test result signal indicating a determination result.

According to a second aspect of the present invention, a method of evaluating a semiconductor device is for performing a self-evaluation relative to a plurality of memory cell array units inside the semiconductor device including the memory cell array units.

According to the first aspect of the present invention, the method of evaluating the semiconductor device includes the steps of generating a test data piece per test cycle including a writing period and a retrieving period; outputting the test data piece as an expected value data piece; writing the test data piece in each of the memory cell array units concurrently during the writing period of the test cycle; retrieving the test data piece from each of the memory cell array units concurrently to obtain a retrieved data piece during the retrieving period; and generating a test result signal indicating whether each of the retrieved data pieces matches the expected value data piece.

### BRIEF DESCRIPTION OF THE DRAWINGS

FIG. 1 is a block diagram showing a configuration of a semiconductor memory as a semiconductor device according to a first embodiment of the present invention;

FIG. 2 is a block diagram showing a configuration of a test circuit of the semiconductor device according to the first embodiment of the present invention;

FIG. 3 is a timing chart showing an example of an internal operation of the test circuit of the semiconductor device during an evaluation according to the first embodiment of the present invention;

FIG. 4 is a block diagram showing a configuration of a test circuit of a semiconductor device according to a second embodiment of the present invention; and

FIG. 5 is a block diagram showing a configuration of a test circuit of a semiconductor device according to a third embodiment of the present invention.

### DETAILED DESCRIPTION OF PREFERRED EMBODIMENTS

Hereunder, preferred embodiments of the present invention will be explained with reference to the accompanying drawings.

### First Embodiment

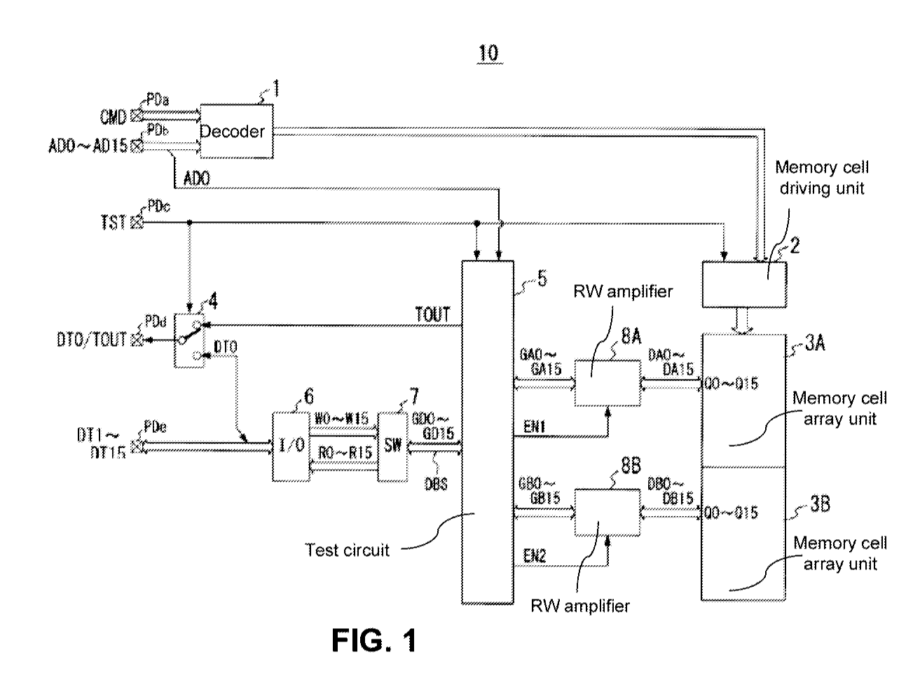

A first embodiment of the present invention will be explained. FIG. 1 is a block diagram showing a configuration of a semiconductor memory 10 as a semiconductor device according to a first embodiment of the present invention.

In the first embodiment, the semiconductor memory 10 is formed of, for example, an SDRAM (Synchronous Dynamic Random Access Memory). As shown in FIG. 1, the semiconductor memory 10 includes a decoder 1; a memory cell driving unit 2; a memory cell array unit 3A; a memory cell array unit 3B; a test result outputting switch 4; a test circuit 5; a data input/output circuit 6; a data switch 7; a read/write amplifier (referred to as an RW amplifier) 8A; and a read/write amplifier (referred to as an RW amplifier) 8B.

In the first embodiment, the decoder 1 is configured to generate an access control signal according to a command signal CMD indicating various commands of the SDRAM input through an external terminal group PDa such as a writing command, a retrieving command, a waiting command, a waiting cancel command, and the like. Further, the decoder 1 is configured to supply the access control signal to the memory cell driving unit 2.

In the first embodiment, the decoder 1 is further configured to generate an address control signal for performing an access (writing and retrieving) relative to an address of the memory cell array unit 3A and the memory cell array unit 3B indicated with addresses AD0 to AD15 input through an external terminal group PDb. Further, the decoder 1 is configured to supply the address control signal to the memory cell driving unit 2.

In the first embodiment, the memory cell driving unit 2 is configured to supply a memory driving signal to the memory cell array unit 3A and the memory cell array unit 3B for performing a memory access of contents indicated with the access control signal relative to the address specified with the address control signal when a test signal TST input through an external terminal PDc indicates a normal mode. In other words, the memory cell driving unit 2 is configured to supply the memory driving signal for writing data to the address thus specified, or to supply the memory driving signal for retrieving data from the address thus specified to the memory cell array unit 3A and the memory cell array unit 3B.

In the first embodiment, the memory cell driving unit 2 is configured to generate the memory driving signal a test sequence for writing test data (described later) to the memory cell array unit 3A and the memory cell array unit 3B and sequentially retrieving the test data thus written when the test signal TST indicates a test mode. Further, the memory cell driving unit 2 is configured to supply the memory driving signal thus generated to the memory cell array unit 3A and the memory cell array unit 3B.

In the first embodiment, the memory cell array unit 3A is configured to include a memory area corresponding to a first address group among addresses [0000]h to [FFFF]h represented with addresses AD0 to AD15. The first address group may be an address group with an odd number address. Further, the memory cell array unit 3A includes ports Q0 to Q15 for externally retrieving data for writing per sixteen bits, and for externally being retrieved data stored therein per sixteen bits.

In the first embodiment, the memory cell array unit 3B is configured to include a memory area corresponding to a second address group among the addresses [0000]h to [FFFF]h represented with the addresses AD0 to AD15. Similar to the memory cell array unit 3A, the memory cell array unit 3B includes the ports Q0 to Q15 for externally retrieving data for writing per sixteen bits, and for externally being retrieved data stored therein per sixteen bits.

In the first embodiment, the test result outputting switch 4 is configured to connect the external terminal PDs to the data input/output circuit 6 when the test signal TST represents the normal mode. Accordingly, the test result outputting switch 4 is configured to supply data DT0 input through the external terminal PDd to the data input/output circuit 6. Further, the test result outputting switch 4 is configured to externally output the data DT0 transmitted from the data input/output circuit 6 through the external terminal PDd.

In the first embodiment, the test result outputting switch 4 is configured to connect the external terminal PDs to the test circuit 5 when the test signal TST represents the test mode. Accordingly, the test result outputting switch 4 is configured to externally output a test result signal TOUT (Described later) transmitted from the test circuit 5 to the data input/output circuit 6 through the external terminal PDd. As described above, the external terminal PDd functions as an external terminal shared for externally outputting and inputting the data DT0 and for externally outputting the test result signal TOUT.

In the first embodiment, the data input/output circuit 6 is configured to supply the data DT0 to DT15 for sixteen bits input through the test result outputting switch 4 and an external terminal group PDe to the data switch 7 as writing data W0 to W15. Further, the data input/output circuit 6 is configured to supply retrieving data R0 corresponding to a bit digit “0” among the retrieving data R0 to R15 to the test result outputting switch 4 as the data DT0. Further, the data input/output circuit 6 is configured to externally output the retrieving data R1 to R15 corresponding to the bit digits “1” to “15” as the data DT1 to DT15 through the external terminal group PDe.

In the first embodiment, the data switch 7 is configured to convert the writing data W0 to W15 supplied from the data input/output circuit 6 to data GD0 to GD15. Further, the data switch 7 is configured to supply the data GD0 to GD15 to the test circuit 5 through data bus DBS formed of sixteen lines for transmitting data for the sixteen bits. Further, the data switch 7 is configured to supply the data GD0 to GD15 supplied from the test circuit 5 through the data bus DBS to the data input/output circuit 6 as the writing data R0 to R15.

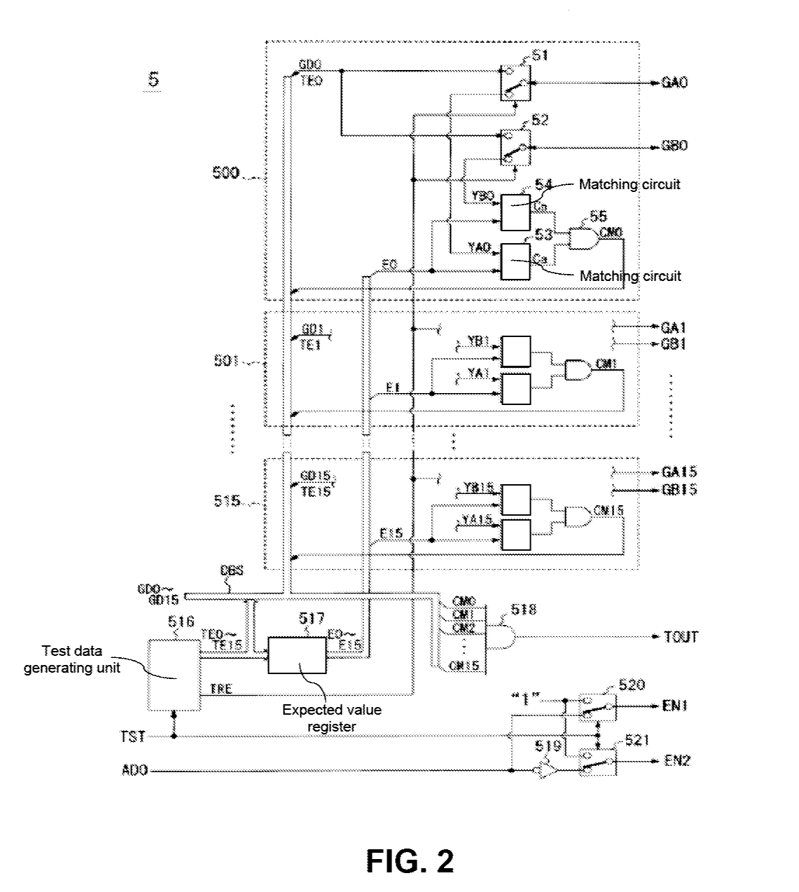

FIG. 2 is a block diagram showing a configuration of the test circuit 5 of the semiconductor device 10 according to the first embodiment of the present invention.

As shown in FIG. 2, the test circuit 5 includes bit matching determining units 500 to 515; a test data generating unit 516; an expected value register 517; an AND gate 518; an inverter 519; a selector 520; and a selector 521.

In the first embodiment, each of the bit matching determining units 500 to 515 is disposed corresponding to each bit of the data GD0 to GD15 of the sixteen bits. The bit matching determining units 500 to 515 have an identical inside configuration. That is, each of the bit matching determining units 500 to 515 includes a data relay switch 51; a data relay switch 52; a matching circuit 53; a matching circuit 54; and an AND gate 55.

In the first embodiment, the data relay switch 51 of the bit matching determining unit 500 is configured to supply the data GA0 supplied from the RW amplifier 8A to the matching circuit 53 as test retrieving data YA0 when a test retrieving signal TRE indicating enablement of test retrieving is supplied to the data relay switch 51. On the other hand, when the test retrieving signal TRE indicating disablement of the test retrieving is supplied to the data relay switch 51, the data relay switch 51 of the bit matching determining unit 500 is configured to transmit the data GA0 supplied from the RW amplifier 8A to the data bus DBS as the data GD0. Further, the data relay switch 51 of the bit matching determining unit 500 is configured to supply the data GD0 or the test data TE0 supplied through the data bus DBS to the RW amplifier 8A as the writing data GA0.

In the first embodiment, the data relay switch 52 of the bit matching determining unit 500 is configured to supply the data GB0 supplied from the RW amplifier 8B to the matching circuit 54 as test retrieving data YB0 when the test retrieving signal TRE indicating enablement of the test retrieving is supplied to the data relay switch 52. On the other hand, when the test retrieving signal TRE indicating disablement of the test retrieving is supplied to the data relay switch 52, the data relay switch 52 of the bit matching determining unit 500 is configured to transmit the data GB0 supplied from the RW amplifier 8B to the data bus DBS as the data GD0. Further, the data relay switch 52 of the bit matching determining unit 500 is configured to supply the data GD0 or the test data TE0 supplied through the data bus DBS to the RW amplifier 8B as the writing data GB0.

In the first embodiment, the matching circuit 53 of the bit matching determining unit 500 is formed of, for example, an exclusive NOR circuit. Further, the matching circuit 53 of the bit matching determining unit 500 is configured to generate a matching determining signal Ca. When the test retrieving data YA0 has a logic level same as that of the expected value data E0, the matching determining signal Ca has the logic level “1”. When the test retrieving data YA0 has the logic level different from that of the expected value data E0, the matching determining signal Ca has the logic level “0”. Further, the matching circuit 53 of the bit matching determining unit 500 is configured to supply the matching determining signal Ca to the AND gate 55 as a first logic AND gate.

In the first embodiment, the matching circuit 54 of the bit matching determining unit 500 is formed of, for example, an exclusive NOR circuit. Further, the matching circuit 54 of the bit matching determining unit 500 is configured to generate a matching determining signal Cb. When the test retrieving data YB0 has a logic level same as that of the expected value data E0, the matching determining signal Cb has the logic level “1”. When the test retrieving data YB0 has the logic level different from that of the expected value data E0, the matching determining signal Cb has the logic level “0”. Further, the matching circuit 54 of the bit matching determining unit 500 is configured to supply the matching determining signal Cb to the AND gate 55 as a first logic AND gate.

In the first embodiment, the AND gate 55 of the bit matching determining unit 500 is configured to generate a bit matching determining signal CM0. When the matching determining signal Ca and the matching determining signal Cb have the logic level “1”, the bit matching determining signal CM0 has the logic level “1”. When one or both of the matching determining signal Ca and the matching determining signal Cb have the logic level “0”, the bit matching determining signal CM0 has the logic level “0”. Further, the AND gate 55 of the bit matching determining unit 500 is configured to supply the bit matching determining signal CM0 to the data bus DBS.

In the first embodiment, the data relay switch 51 of the bit matching determining unit 501 is configured to supply the data GA1 supplied from the RW amplifier 8A to the matching circuit 53 as test retrieving data YA1 when the test retrieving signal TRE indicating enablement of the test retrieving is supplied to the data relay switch 51. On the other hand, when the test retrieving signal TRE indicating disablement of the test retrieving is supplied to the data relay switch 51, the data relay switch 51 of the bit matching determining unit 501 is configured to transmit the data GA1 supplied from the RW amplifier 8A to the data bus DBS as the data GD1. Further, the data relay switch 51 of the bit matching determining unit 501 is configured to supply the data GD1 or the test data TE1 supplied through the data bus DBS to the RW amplifier 8A as the writing data GA1.

In the first embodiment, the data relay switch 52 of the bit matching determining unit 501 is configured to supply the data GB1 supplied from the RW amplifier 8B to the matching circuit 54 as the test retrieving data YB1 when the test retrieving signal TRE indicating enablement of the test retrieving is supplied to the data relay switch 52. On the other hand, when the test retrieving signal TRE indicating disablement of the test retrieving is supplied to the data relay switch 52, the data relay switch 52 of the bit matching determining unit 501 is configured to transmit the data GB1 supplied from the RW amplifier 8B to the data bus DBS as the data GD1. Further, the data relay switch 52 of the bit matching determining unit 501 is configured to supply the data GD1 or the test data TE1 supplied through the data bus DBS to the RW amplifier 8B as the writing data GB1.

In the first embodiment, the matching circuit 53 of the bit matching determining unit 501 is configured to generate the matching determining signal Ca. When the test retrieving data YA1 has the logic level same as that of the expected value data E1, the matching determining signal Ca has the logic level “1”. When the test retrieving data YA1 has the logic level different from that of the expected value data E1, the matching determining signal Ca has the logic level “0”. Further, the matching circuit 53 of the bit matching determining unit 501 is configured to supply the matching determining signal Ca to the AND gate 55.

In the first embodiment, the matching circuit 54 of the bit matching determining unit 501 is configured to generate the matching determining signal Cb. When the test retrieving data YB1 has the logic level same as that of the expected value data E1, the matching determining signal Cb has the logic level “1”. When the test retrieving data YB1 has the logic level different from that of the expected value data E1, the matching determining signal Cb has the logic level “0”. Further, the matching circuit 54 of the bit matching determining unit 501 is configured to supply the matching determining signal Cb to the AND gate 55.

In the first embodiment, the AND gate 55 of the bit matching determining unit 501 is configured to generate a bit matching determining signal CM1. When the matching determining signal Ca and the matching determining signal Cb have the logic level “1”, the bit matching determining signal CM1 has the logic level “1”. When one or both of the matching determining signal Ca and the matching determining signal Cb have the logic level “0”, the bit matching determining signal CM1 has the logic level “0”. Further, the AND gate 55 of the bit matching determining unit 501 is configured to supply the bit matching determining signal CM1 to the data bus DBS.

In the first embodiment, similarly, the data relay switch 51 of each of the bit matching determining units 500 to 515 is configured to supply the data GA(n) (n is a natural integer between 2 and 15) supplied from the RW amplifier 8A to the matching circuit 53 as the test retrieving data YA(n) when the test retrieving signal TRE indicating enablement of the test retrieving is supplied to the data relay switch 51. On the other hand, when the test retrieving signal TRE indicating disablement of the test retrieving is supplied to the data relay switch 51, the data relay switch 51 of each of the bit matching determining units 500 to 515 is configured to transmit the data GA(n) supplied from the RW amplifier 8A to the data bus DBS as the data GD(n). Further, the data relay switch 51 of each of the bit matching determining units 500 to 515 is configured to supply the data GD(n) or the test data TE(n) supplied through the data bus DBS to the RW amplifier 8A as the writing data GA(n).

In the first embodiment, the data relay switch 52 of each of the bit matching determining units 500 to 515 is configured to supply the data GB(n) supplied from the RW amplifier 8B to the matching circuit 54 as the test retrieving data YB(n) when the test retrieving signal TRE indicating enablement of the test retrieving is supplied to the data relay switch 52. On the other hand, when the test retrieving signal TRE indicating disablement of the test retrieving is supplied to the data relay switch 52, the data relay switch 52 of each of the bit matching determining units 500 to 515 is configured to transmit the data GB(n) supplied from the RW amplifier 8B to the data bus DBS as the data GD(n). Further, the data relay switch 52 of each of the bit matching determining units 500 to 515 is configured to supply the data GD(n) or the test data TE(n) supplied through the data bus DBS to the RW amplifier 8B as the writing data GB(n).

In the first embodiment, the matching circuit 53 of each of the bit matching determining units 500 to 515 is configured to generate the matching determining signal Ca. When the test retrieving data YA(n) has the logic level same as that of the expected value data E(n), the matching determining signal Ca has the logic level “1”. When the test retrieving data YA(n) has the logic level different from that of the expected value data E(n), the matching determining signal Ca has the logic level “0”. Further, the matching circuit 53 of each of the bit matching determining units 500 to 515 is configured to supply the matching determining signal Ca to the AND gate 55.

In the first embodiment, the matching circuit 54 of each of the bit matching determining units 500 to 515 is configured to generate the matching determining signal Cb. When the test retrieving data YB(n) has the logic level same as that of the expected value data E(n), the matching determining signal Cb has the logic level “1”. When the test retrieving data YB(n) has the logic level different from that of the expected value data E(n), the matching determining signal Cb has the logic level “0”. Further, the matching circuit 54 of each of the bit matching determining units 500 to 515 is configured to supply the matching determining signal Cb to the AND gate 55.

In the first embodiment, the AND gate 55 of each of the bit matching determining units 500 to 515 is configured to generate a bit matching determining signal CM(n). When the matching determining signal Ca and the matching determining signal Cb have the logic level “1”, the bit matching determining signal CM(n) has the logic level “1”. When one or both of the matching determining signal Ca and the matching determining signal Cb have the logic level “0”, the bit matching determining signal CM(n) has the logic level “0”. Further, the AND gate 55 of each of the bit matching determining units 500 to 515 is configured to supply the bit matching determining signal CM(n) to the data bus DBS.

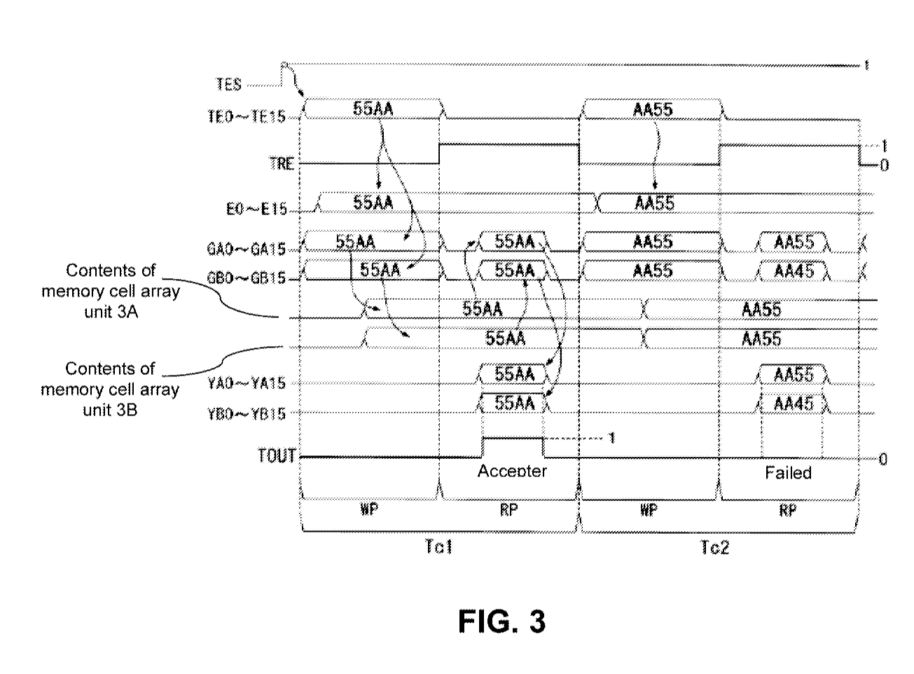

FIG. 3 is a timing chart showing an example of an internal operation of the test circuit 5 of the semiconductor device 10 during an evaluation according to the first embodiment of the present invention.

As shown in FIG. 3, when the test signal TST is transited from the logic level “0” indicating the normal mode to the logic level “1” indicating the test mode, the test data generating unit 516 is configured to start generating the test data TE0 to TE15 of the sixteen bits. More specifically, as shown in FIG. 3, during the test cycle Tc1, the test data generating unit 516 is configured to generate the test data TE0 to TE15 indicating [55AA]h.

In the first embodiment, the test data generating unit 516 is configured to supply the test data TE0 to TE15 to the expected value register 517 and the bit matching determining units 500 to 515 over the writing period WP of the test cycle Tc1. Further, during the test cycle Tc2, the test data generating unit 516 is configured to generate the test data TE0 to TE15 indicating [AA55]h. Further, the test data generating unit 516 is configured to supply the test data TE0 to TE15 to the expected value register 517 and the bit matching determining units 500 to 515 over the writing period WP of the test cycle Tc2.

In the first embodiment, the test data generating unit 516 is configured to supply the test retrieving signal TRE having the logic level “1” indicating enablement of the test retrieving to the bit matching determining units 500 to 515 only during the retrieving period RP of each of the test cycle Tc1 and the test cycle Tc2.

In the first embodiment, as shown in FIG. 3, the expected value register 517 is configured to retrieve and store the test data TE0 to TE15. Further, the expected value register 517 is configured to supply the test data TE0 to TE15 to the bit matching determining units 500 to 515 as the expected value data E0 to E15.

In the first embodiment, the AND gate 518 as a second logic AND gate is configured to generate the test result signal TOUT. The test result signal TOUT represents “Passed” when all of the bit matching determining signals CM0 to CM15 transmitted from the bit matching determining units 500 to 515 to the data bus DBS have the logic level “1”. On the other hand, when at least one of the bit matching determining signals CM0 to CM15 has the logic level “0”, the test result signal TOUT represents “Failed”

In the first embodiment, the inverter 519 is configured to supply an inverted address signal having the logic level inverted from that of the address AD0 as the lowest bit of the addresses AD0 to AD15 to the selector 521.

In the first embodiment, the selector 520 is configured to generate the enable signal EN1 having the logic level indicated with the address AD0 when the test signal TST indicates the normal mode. On the other hand, when the test signal TST indicates the test mode, the selector 520 is configured to generate the enable signal EN1 having the logic level “1”, so that the RW amplifier 8A is set to the enable state.

In the first embodiment, the selector 521 is configured to generate the enable signal EN2 having the logic level inverted from that of the address AD0 when the test signal TST indicates the normal mode. On the other hand, when the test signal TST indicates the test mode, the selector 520 is configured to generate the enable signal EN2 having the logic level “1”, so that the RW amplifier 8B is set to the enable state.

In the first embodiment, with the configuration shown in FIG. 2, the test circuit 5 generates the enable signal EN1 and the enable signal EN2 according to the address AD0 as the lowest bit when the test signal TST indicates the normal mode. As a result, one of the RW amplifier 8A and the RW amplifier 8B is set to the enable state, and the other of the RW amplifier 8A and the RW amplifier 8B is set to the disable state. For example, when the test circuit 5 generates the enable signal EN1 (the enable signal EN2) having the logic level “1”, the RW amplifier 8A (the RW amplifier 8B) is set to the enable state. When the test circuit 5 generates the enable signal EN1 (the enable signal EN2) having the logic level “0”, the RW amplifier 8A (the RW amplifier 8B) is set to the disable state.

Further, in the first embodiment, when the test signal TST indicates the normal mode, the test circuit 5 supplies the writing data GD0 to GD15 supplied from the data switch 7 to the RW amplifier 8A as the data GA0 to GA15. Further, the test circuit 5 supplies the writing data GD0 to GD15 supplied from the data switch 7 to the RW amplifier 8B as the data GB0 to GB15.

Further, in the first embodiment, when the test signal TST indicates the normal mode, the test circuit 5 relays and supplies the data GA0 to GA15 to the data switch 7 as the data GD0 to GD15 through the data bus DBS when the data GA0 to GA15 as the retrieving data are supplied from the RW amplifier 8A.

Further, in the first embodiment, when the test signal TST indicates the normal mode, the test circuit 5 relays and supplies the data GB0 to GB15 to the data switch 7 as the data GD0 to GD15 through the data bus DBS when the data GB0 to GB15 as the retrieving data are supplied from the RW amplifier 8B.

On the other hand, in the first embodiment, when the test signal TST indicates the test mode, the test circuit 5 generates the enable signal EN1 and the enable signal EN2 having the logic level “1”, so that both of the RW amplifier 8A and the RW amplifier 8B are set to the enable state. Further, the test circuit 5 supplies the enable signal EN1 to the RW amplifier 8A, and supplies the enable signal EN2 to the RW amplifier 8B.

Further, in the first embodiment, when the test signal TST indicates the test mode, the test circuit 5 supplies the test data of the sixteen bits internally generated (described later) to the RW amplifier 8A and the RW amplifier 8B as the data GA0 to GA15 and GB0 to GB15 for the test writing.

Further, in the first embodiment, when the test signal TST indicates the test mode, the test circuit 5 retrieves the data GA0 to GA15 and GB0 to GB15 when the data GA0 to GA15 for the test retrieving are supplied from the RW amplifier 8A, and the data GB0 to GB15 for the test retrieving are supplied from the RW amplifier 8B.

In the next step, the test circuit 5 compares the data GA0 to GA15 thus retrieved as the test retrieving data with the data GB0 to GB15 thus retrieved as the test retrieving data. Then, the test circuit 5 generates the test result signal TOUT indicating the test result, and supplies the test result signal TOU to the test result outputting switch 4. More specifically, when the data GA0 to GA15 match the data GB0 to GB15, the test circuit 5 generates and supplies the test result signal TOUT indicating the test result “Passed’ to the test result outputting switch 4. On the other hand, when the data GA0 to GA15 do not match the data GB0 to GB15, the test circuit 5 generates and supplies the test result signal TOUT indicating the test result “Failed’ to the test result outputting switch 4.

In the first embodiment, the RW amplifier 8A is configured to be operable only during the enable signal EN1 indicating enablement is supplied to the RW amplifier 8A. When the data DA0 to DA15 of the sixteen bits are retrieved through the ports Q0 to Q15 of the memory cell array unit 3A, the RW amplifier 8A supplies the data DA0 to DA15 to the test circuit 5 as the data GA0 to GA15. When the data GA0 to GA15 of the sixteen bits for writing are supplied from the test circuit 5, the RW amplifier 8A supplies the data GA0 to GA15 to the ports Q0 to Q15 of the memory cell array unit 3A as the data DA0 to DA15 for writing.

In this step, when the memory driving signal is supplied to the memory cell array unit 3A so that the data is written in the address specified with the addresses AD0 to AD15, the memory cell array unit 3A stores the data DA0 to DA15 supplied from the RW amplifier 8A to the address thus specified. On the other hand, when the memory driving signal is supplied to the memory cell array unit 3A from the address thus specified so that the data is retrieved from the address, the memory cell array unit 3A supplies the data of the sixteen bits thus retrieved from the address thus specified to the RW amplifier 8A as the data DA0 to DA15.

In the first embodiment, the RW amplifier 8B is configured to be operable only during the enable signal EN2 indicating enablement is supplied to the RW amplifier 8B. When the data DB0 to DB15 of the sixteen bits are retrieved through the ports Q0 to Q15 of the memory cell array unit 3B, the RW amplifier 8B supplies the data DB0 to DB15 to the test circuit 5 as the data GB0 to GB15. When the data GB0 to GB15 of the sixteen bits for writing are supplied from the test circuit 5, the RW amplifier 8B supplies the data GB0 to GB15 to the ports Q0 to Q15 of the memory cell array unit 3B as the data DB0 to DB15 for writing.

In this step, when the memory driving signal is supplied to the memory cell array unit 3B so that the data is written in the address specified with the addresses AD0 to AD15, the memory cell array unit 3A stores the data DB0 to DB15 supplied from the RW amplifier 8B to the address thus specified. On the other hand, when the memory driving signal is supplied to the memory cell array unit 3B from the address thus specified so that the data is retrieved from the address, the memory cell array unit 3B supplies the data of the sixteen bits thus retrieved from the address thus specified to the RW amplifier 8B as the data DB0 to DB15.

With the configuration shown in FIGS. 1 and 2, when the test signal TST indicates the normal mode, the test circuit 5 of the semiconductor memory 10 accesses only one of the memory cell array unit 3A or the memory cell array unit 3B as the access subject according to the address AD0. Then, the test circuit 5 writes or retrieves the data only relative to one of the memory cell array unit 3A or the memory cell array unit 3B as the access subject.

On the other hand, when the test signal TST indicates the test mode, the test circuit 5 and the memory cell driving unit 2 of the semiconductor memory 10 perform the self-evaluation test relative to the memory cell array unit 3A or the memory cell array unit 3B.

An operation of the self-evaluation test upon shipping the semiconductor memory 10 will be explained next with the reference to the internal operation of the test circuit 5 during the test cycle Tc1 shown in FIG. 3 as an example.

As shown in FIG. 3, according to the test signal TST having the logic level “1” indicating the test mode, the test data generating unit 516 is configured to generate the test data TE0 to TE15 indicating [55AA]h during the test cycle Tc1. Further, the test data generating unit 516 transmits the test data TE0 to TE15 to the data bus DBS during the writing period WP of the test cycle Tc1. Further, during the writing period WP of the test cycle Tc1, the bit matching determining units 500 to 515 supply the test data TE0 to TE15 indicating [55AA]h to the RW amplifier 8A and the RW amplifier 8B as the data GA0 to GA15 and GB0 to GB15 according to the test retrieving signal TRE having the logic level “0” indicating disablement of the test retrieving.

Further, during the period of time when the test signal TST having the logic level “1” indicating the test mode is supplied, the selector 520 and the selector 521 supply the enable signal EN1 having the logic level “1” to the RW amplifier 8A and the RW amplifier 8B, so that the RW amplifier 8A and the RW amplifier 8B are set to the enable state. As a result, during the writing period WP of the test cycle Tc1, the data GA0 to GA15 and GB0 to GB15 indicating [55AA]h are concurrently supplied to the memory cell array unit 3A and the memory cell array unit 3B. Further, according to the test signal TST having the logic level “1” indicating the test mode, the memory cell driving unit 2 sequentially writes the test data to each address of the memory cell array unit 3A and the memory cell array unit 3B. Further, the memory cell driving unit 2 supplies the memory driving signal to the memory cell array unit 3A and the memory cell array unit 3B according to the test sequence for sequentially retrieving the test data thus written.

For example, as shown in FIG. 3, during the writing period WP of the test cycle Tc1, the memory cell driving unit 2 supplies the writing driving signal to each address of the memory cell array unit 3A and the memory cell array unit 3B, so that the data is sequentially written in each address of the memory cell array unit 3A and the memory cell array unit 3B. As a result, as shown in FIG. 3, the data indicating [55AA]h is concurrently written in each address of the memory cell array unit 3A and the memory cell array unit 3B. At this moment, the expected value register 517 retrieves and stores the test data TE0 to TE15 indicating [55AA]h. Further, the expected value register 517 supplies the test data TE0 to TE15 to the bit matching determining units 500 to 515 as the expected value data E0 to E15.

In the next step, during the retrieving period RP of the test cycle Tc1, the memory cell driving unit 2 supplies the retrieving driving signal to each address of the memory cell array unit 3A and the memory cell array unit 3B, so that the data is sequentially retrieved from each address of the memory cell array unit 3A and the memory cell array unit 3B. As a result, the data is concurrently retrieved from each address of the memory cell array unit 3A and the memory cell array unit 3B. At this moment, the data DA0 to DA15 retrieved from the memory cell array unit 3A are supplied to the bit matching determining units 500 to 515 as the data GA0 to GA15 through the RW amplifier 8A. Further, the data DB0 to DB15 retrieved from the memory cell array unit 3B are supplied to the bit matching determining units 500 to 515 as the data GB0 to GB15 through the RW amplifier 8B.

Further, during the retrieving period RP of the test cycle Tc1, the bit matching determining units 500 to 515 retrieve the data DA0 to DA15 retrieved from the memory cell array unit 3A and the data DB0 to DB15 retrieved from the memory cell array unit 3B as the test retrieving data YA0 to YA15 and YB0 to YB15 through the data relay switch 51 and the data relay switch 52.

In the next step, in the bit matching determining units 500 to 515, the matching circuit 53 determines whether the expected value data E0 to E15 stored in the expected value register 517 match the test retrieving data YA0 to YA15. Further, the matching circuit 54 determines whether the expected value data E0 to E15 stored in the expected value register 517 match the test retrieving data YB0 to YB15. At this moment, as shown in FIG. 3, only when the test retrieving data YA0 to YA15 match the expected value data E0 to E15, and the test retrieving data YB0 to YB15 match the expected value data E0 to E15, the test result signal TOUT having the logic value “1” representing “Passed” is transmitted to the test result outputting switch 4 through the AND gate 55 and the AND gate 518.

It should be noted that, during the period of time when the test signal TST having the logic level “1” indicating the test mode is supplied, the test result outputting switch 4 externally outputs the test result signal TOUT through the external terminal PDd.

More specifically, the test circuit 5 and the memory cell driving unit 2 generate the test data TE0 and TE15, and write the test data TE0 to TE15 into the memory cell array unit 3A and the memory cell array unit 3B concurrently. In the next step, the test circuit 5 retrieves the test retrieving data YA0 to YA15 and the test retrieving data YB0 to YB15 from each address of the memory cell array unit 3A and the memory cell array unit 3B concurrently. Further, the test circuit 5 determines whether the test retrieving data YA0 to YA15 and the test retrieving data YB0 to YB15 retrieved from each address of the memory cell array unit 3A and the memory cell array unit 3B match the expected value data E0 to E15. When both the test retrieving data YA0 to YA15 and the test retrieving data YB0 to YB15 match the expected value data E0 to E15, the test circuit 5 transmits the test result signal TOUT representing “Passed”. When at least ones of the test retrieving data YA0 to YA15 and the test retrieving data YB0 to YB15 do not match the expected value data E0 to E15, the test circuit 5 transmits the test result signal TOUT representing “Failed”.

In the first embodiment, a tester (not shown) may be provided for monitoring the test result signal TOUT transmitted from the external terminal PDd of the semiconductor memory 10. Accordingly, it is possible to determine the evaluation result of the semiconductor memory 10 as the test subject.

Further, in the test circuit 5 shown in FIG. 3, the test data TE0 to TE15 are concurrently written in the memory cell array unit 3A and the memory cell array unit 3B in the test mode. Further, in the test mode, the test retrieving data YA0 to YA15 and the test retrieving data YB0 to YB15 are concurrently retrieved from the memory cell array unit 3A and the memory cell array unit 3B. Then, it is concurrently determined whether the test retrieving data YA0 to YA15 and the test retrieving data YB0 to YB15 match the expected value data E0 to E15.

More specifically, during the test cycle Tc including the writing period WP and the retrieving period RP, the evaluation is concurrently performed relative to the memory cell array unit 3A and the memory cell array unit 3B. Accordingly, it is possible to shorten the evaluation time.

In the first embodiment, as described above, the test data TE0 to TE15 for the test writing are supplied to the bit matching determining units 500 to 515 through the data bus BDS. Alternatively, it may be configured such that the test data TE0 to TE15 for the test writing are supplied to the bit matching determining units 500 to 515 through a test data bus disposed separately from the data bus BDS

### Second Embodiment

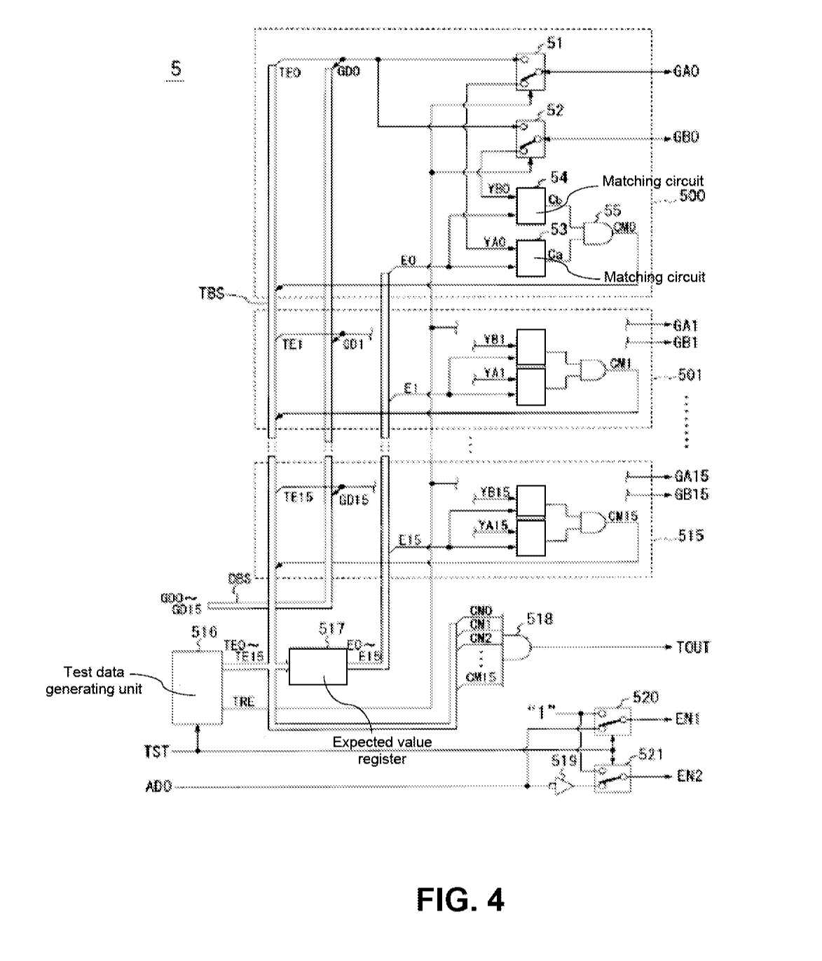

A second embodiment of the present invention will be explained next with reference to FIG. 4. FIG. 4 is a block diagram showing a configuration of the test circuit 5 of a semiconductor device according to the second embodiment of the present invention.

In the first embodiment, as described above, the test data TE0 to TE15 for the test writing are supplied to the bit matching determining units 500 to 515 through the data bus BDS. In the second embodiment, it is configured such that the test data TE0 to TE15 for the test writing are supplied to the bit matching determining units 500 to 515 through a test data bus TBS disposed separately from the data bus BDS.

As shown in FIG. 4, the test data bus TBS formed of sixteen lines for transmitting data for the sixteen bits is provided to the configuration shown in FIG. 2. It should be noted that the test data generating unit 516 generates the test data TE0 to TE15, and supplies the test data TE0 to TE15 to the data relay switch 51 of each of the bit matching determining units 500 to 515 through the test data bus TBS. Further, in the second embodiment, it is configured such that the bit matching determining signals CM0 to CM15 transmitted from the AND gate 55 of each of the bit matching determining units 500 to 515 are supplied to the AND gate 518 through the test data bus TBS.

In the configuration in the second embodiment shown in FIG. 4, as well as in the configuration in the first embodiment shown in FIG. 2, the test data generating unit 516 supplies the test data piece (TE) formed of the first bit to the n-th bit to the data relay switch 51 and the data relay switch 52 through the data bus DBS or the test data bus TBS formed of the n lines. At this moment, the matching circuit 53 and the matching circuit 54 of each of the bit matching determining units 500 to 515 in the matching circuit 53, the matching circuit 54, and the AND gate 518 determines whether the retrieving data piece (YA, YB) retrieved from the memory cell array unit 3A and the memory cell array unit 3B match the expected value data piece (E) per every bit. Accordingly, the matching circuit 53 and the matching circuit 54 of each of the bit matching determining units 500 to 515 generate the matching determining signal Ca and the matching determining signal Cb indicating the determination result per each of the first bit to the n-th bit.

Further, in the second embodiment, the AND gate 55 of each of the bit matching determining units 500 to 515 obtains the logic product per the same bit digit relative to the matching determining signal Ca and the matching determining signal Cb for the memory cell array unit 3A and the memory cell array unit 3B. Further, the AND gate 55 of each of the bit matching determining units 500 to 515 transmits the bit matching determining signals CM0 to CM15 to the data bus DBS or the test data bus TBS. In the next step, the AND gate 518 connected to the data bus DBS or the test data bus TBS obtains the logic product of the bit matching determining signals CM0 to CM15 for the n bits transmitted to the data bus DBS or the test data bus TBS. Further the AND gate 518 generates the logic product result as the test result signal TOUT.

In the configuration in the second embodiment shown in FIG. 4, as well as in the configuration in the first embodiment shown in FIG. 2, the matching circuit 53, the matching circuit 54 and the AND gate 55 are disposed per each bit for obtaining the bit matching determining signals CM0 to CM15 for n bits. Further, the bit matching determining signals CM0 to CM15 are supplied to the AND gate 518 as the single component through the data bus DBS or the test data bus TBS, which is also provided for transmitting the test data piece (TE). Accordingly, it is possible to dispose the AND gate 518 any location along the data bus DBS or the test data bus TBS. As a result, it is possible to obtain the design freedom in the chip to the higher degree, and to integrate the chip to a higher density.

### Third Embodiment

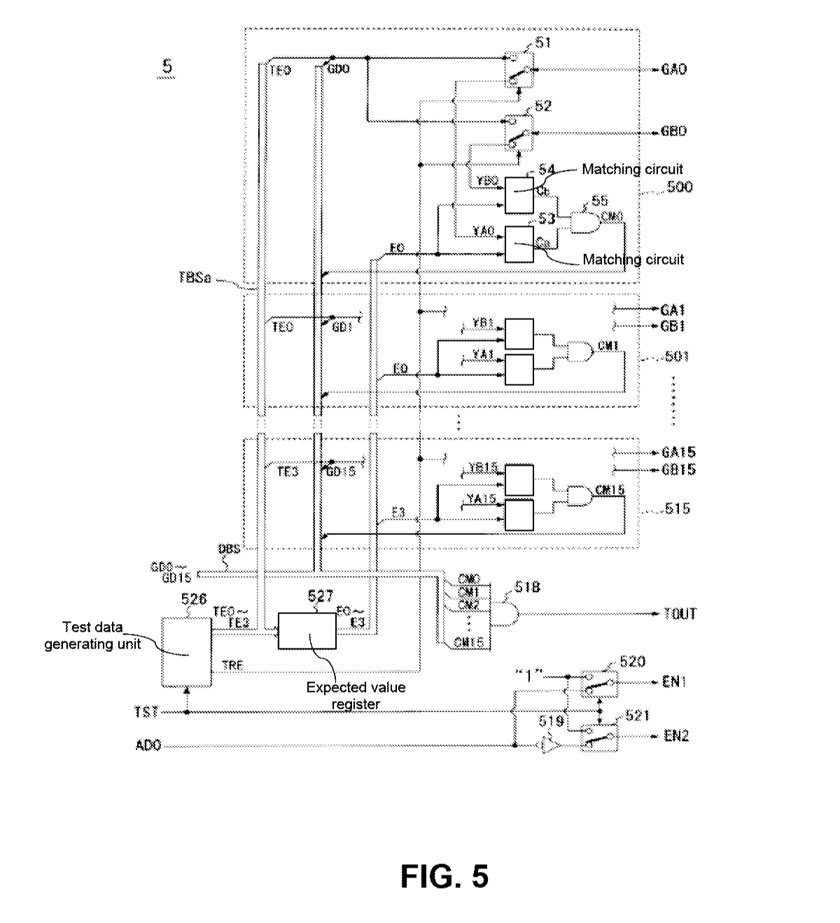

A third embodiment of the present invention will be explained next with reference to FIG. 5. FIG. 5 is a block diagram showing a configuration of the test circuit 5 of a semiconductor device according to a third embodiment of the present invention.

As shown in FIG. 5, instead of the test data generating unit 516 and the expected value register 517 shown in FIG. 4, the test circuit 5 is provided with a test data generating unit 526 and an expected value register 527. Further, instead of the test data bus TBS for the sixteen bits shown in FIG. 4, the test circuit 5 is provided with a test data bus TBSa formed of four lines for transmitting data for the four bits. Other configuration of the test circuit 5 in the third embodiment is similar to that of the test circuit 5 in the second embodiment shown in FIG. 4.

In the third embodiment, in the test circuit 5 shown in FIG. 5, when the test signal TST is transited from the logic level “0” indicating the normal mode to the logic level “1” indicating the test mode, the test data generating unit 526 is configured to start generating the test data TE0 to TE3 of the three bits. Then, the test data generating unit 526 is configured to transmit the test data TE0 to TE3 to the test data but TBSa.

In the third embodiment, the test data generating unit 526 is configured to supply the test data TE0 among the test data TE0 to TE3 to each of the bit matching determining units 500 to 503 through the test data bus TBSa, and to supply the test data TE1 among the test data TE0 to TE3 to each of the bit matching determining units 504 to 507 through the test data bus TBSa. Further, the test data generating unit 526 is configured to supply the test data TE2 among the test data TE0 to TE3 to each of the bit matching determining units 508 to 511 through the test data bus TBSa, and to supply the test data TE3 among the test data TE0 to TE3 to each of the bit matching determining units 512 to 515 through the test data bus TBSa.

In the third embodiment, the test data generating unit 526 is configured to supply the test data TE0 to TE3 to the expected value register 527. Then, the expected value register 527 is configured to retrieve and store the test data TE0 to TE3 of the four bits. Further, the expected value register 527 is configured to supply the test data TE0 to TE3 to the bit matching determining units 500 to 515 as the expected value data E0 to E3.

More specifically, the expected value register 527 is configured to supply the expected value data E0 to each of the bit matching determining units 500 to 503, and to supply the expected value data E1 to each of the bit matching determining units 504 to 507. Further, the expected value register 527 is configured to supply the expected value data E2 to each of the bit matching determining units 508 to 511, and to supply the expected value data E3 to each of the bit matching determining units 512 to 515.

In the third embodiment, in the test circuit 5 shown in FIG. 5, it is configured such that the bit matching determining signals CM0 to CM15 transmitted from the test circuit 55 of each of the bit matching determining units 500 to 515 are supplied to the AND gate 518 through to the data bus DBS.

Accordingly, in the test circuit 5 in the third embodiment shown in FIG. 5, the test data TE0- to TE3 to be written in the memory cell array unit 3A and the memory cell array unit 3B are limited to the sixteen patterns. However, the test data bus TBSa has only the four lines of the four bits. Further, the test data generating unit 526 and the expected value register 527 are configured to process the data of the four bits. Accordingly, in the third embodiment, as opposed to the configuration in the second embodiment shown in FIG. 4, in which the test data bus TBS is formed of the sixteen lines of the sixteen bits, and the test data generating unit 516 and the expected value register 517 are configured to process the data of the sixteen bits, it is possible to reduce the size of the test circuit 5.

It should be noted that, in the test circuit 5 in the third embodiment shown in FIG. 5, the bit number of the test data piece is the four bits that is smaller than the sixteen bits of the retrieving data piece or the writing data piece. Further, it is configured such that the data is supplied through the test data bus TBSa formed of the four lines to the data relay switch 51 and the data relay switch 52 corresponding to each of the sixteen bits. The bit number is not limited to the four bits. It is suffice that the test data piece formed of the first to the p-th bits (p is an integer less than a half of n) can be supplied to the data relay switch 51 and the data relay switch 52 through the data bus formed of the p number of lines.

The disclosure of Japanese Patent Application No. 2013-147707, filed on Jul. 16, 2013, is incorporated in the application by reference.

While the invention has been explained with reference to the specific embodiments of the invention, the explanation is illustrative and the invention is limited only by the appended claims.

What is claimed is:

1. A semiconductor device, comprising:
a plurality of memory cell array units; and
a test circuit unit for performing a self-evaluation test relative to the memory cell array units,
wherein said test circuit unit includes:
a test data generating unit configured to generate a test data piece per test cycle including a writing period and a retrieving period;
an expected value register configured to retrieve and store the test data piece, and to output the test data piece as an expected value data piece;
a memory cell driving unit configured to supply a writing driving signal to the memory cell array units during the writing period of the test cycle, and to supply a retrieving driving signal to the memory cell array units during the retrieving period of the test cycle;
a data relay switching unit configured to supply the test data piece to the memory cell array units during the writing period of the test cycle, and to retrieve and output retrieved data piece retrieved from the memory cell array units during the retrieving period of the test cycle; and
a determining unit configured to determine whether the retrieved data piece output from the data relay switching unit matches the expected value data piece, and to generate a test result signal indicating a determination result.

2. The semiconductor device according to claim 1, wherein said test data generating unit is configured to generate the test data piece of a first to an n-th bits (n is an integer greater than two) so that the test data piece is transmitted to the data relay switching unit through a data bus formed of an n-number of lines,
said expected value register is configured to output the expected value data piece of the first to the n-th bits, and
said data relay switching unit is configured to output the retrieved data piece of the first to the n-th bits.

3. The semiconductor device according to claim 2, wherein said determining unit includes a matching circuit configured to determine whether the retrieved data piece matches the expected value data piece per each of the first to the n-th bits, and to generate a matching determining signal indicating a matching determination result per each of the first to the n-th bits;
a first logic gate configured to obtain a first logic product according to the matching determining signal per each of the first to the n-th bits, and to output a bit mating determining signal per each of the first to the n-th bits indicating a logic product result; and
a second logic gate configured to obtain a second logic product of the matching determining signal of the first to the n-th bits, and to output a second logic product result as the test result signal.

4. The semiconductor device according to claim 1, wherein said expected value register is configured to output the expected value data piece of a first to an n-th bits n is an integer greater than two),
said data relay switching unit is configured to output the retrieved data piece of the first to the n-th bits, and
said test data generating unit is configured to generate the test data piece of the first to a p-th bits (p is an integer less than a half of n) so that the test data piece is transmitted to the data relay switching unit through a data bus formed of a p-number of lines.

5. A method of evaluating a semiconductor device for performing a self-evaluation relative to a plurality of memory cell array units disposed inside the semiconductor device, comprising the steps of:
generating a test data piece per test cycle including a writing period and a retrieving period;
outputting the test data piece as an expected value data piece;
writing the test data piece in each of the memory cell array units concurrently during the writing period of the test cycle;
retrieving the test data piece from each of the memory cell array units concurrently to obtain a retrieved data piece during the retrieving period; and
generating a test result signal indicating whether the retrieved data piece matches the expected value data piece.
